(19) United States
(12) Patent Application Publication
(10) Pub. No.: US 2012/0009340 A1
(43) Pub. Date: Jan. 12, 2012

(54) METHOD FOR PRODUCING DEFORMABLE CORROSION PROTECTION LAYERS ON METAL SURFACES

(75) Inventors: Stefan Sepeur, Wadgassen (DE); Stefan Goedicke, Neunkirchen (DE); Christine Breyer, Saarbruecken (DE); Christina Tasch, Saarbruecken (DE)

(73) Assignee: NANO-X GmbH, Saarbruecken (DE)

(21) Appl. No.: 12/998,405

(22) PCT Filed: Sep. 17, 2009
(86) PCT No.: PCT/DE2009/075049

§ 371 Date: Jun. 13, 2011

(30) Foreign Application Priority Data
Oct. 16, 2008 (DE) 10 2008 051 883.2

(51) Int. Cl. B05D 5/00; B05D 1/18; C25D 15/00; B05D 1/28; C23C 16/44; B05D 1/12; B05D 3/12

(52) U.S. Cl. 427/180; 427/372.2; 205/109

(57) ABSTRACT

The invention relates to a method for producing deformable corrosion protection layers on a metallic surface and to use of the method. In order to create an economical process for cathodic corrosion protection of metal for a broad range of applications, the invention proposes a method for producing deformable corrosion protection lavers on a metallic surface, consisting of the following steps: a) Mixing 5 to 95 wt. % metallic magnesium, zinc, aluminum or titanium particles, or mixtures or alloys containing at least one of these metals, in the form of pigments, powders, pastes (flakes) or pellets with 5 to 95 wt. % of at least one metal compound, wherein a reaction between the metal particles and metal compound(s) results in surface-modified metal particles; b) Applying the resulting surface-modified metal particles to the metallic surface; c) Hardening the layer produced from the surface-modified metal particles at temperatures between room temperature and 350° C. It has been shown within the context of the invention that the metal substrate coated according to the method of the invention can be deformed, overpainted, welded, coated and colored, and reflects heat.

The invention relates to a method for producing deformable corrosion protection layers on a metallic surface and to use of the method.

Zinc coatings for the active protection of steel against corrosion are known from the prior art. Zinc melts at 415° C. and boils at 907° C., which means that the temperature window within which it can be used is limited to approx. 300° C. Under long-term exposure to high temperatures, zinc corrodes very quickly and loses its anti-corrosion effect.

A further limitation of zinc is its normal standard potential of −0.76 V. For iron, which has a standard potential of −0.4 V, zinc is able to provide adequate cathodic protection. However, if components of steel and aluminium (normal standard potential of aluminium =−1.66 V) are joined together, contact erosion ensues and the aluminium is sacrificed. For this reason, particularly in the automotive industry, parts made of aluminium alloys or magnesium alloys are prevented at substantial expense from making direct contact with parts made of steel and of galvanized steel.

Zinc flake coatings are also known from the prior art. These consist of zinc pigments (flakes) in a matrix containing, by way of example, organic binders or siloxanes, and are cured thermally at temperatures above 250° C. The systems offered by the various manufacturers differ in containing chromium VI or being free of chromium VI, and in secondary components such as various cobalt binders, flexibility-enhancing components, waxes, and the like. Especially in corrosion tests such as the neutral salt spray test, these zinc flake coatings provide distinctly better corrosion protection than zinc-metal coatings of comparable thickness. However, they are not suitable for forming processes, such as cold and hot forming, bending or flanging.

The disadvantages described above concerning limitations in long-term high-temperature stability and use on material composites, for example of steel and aluminium or steel and magnesium, apply here, in the same way.

In the prior art, magnesium-containing coatings are disclosed that protect steel from corrosion by virtue of their low standard potential. These are deposited electrolytically, as described, for example, in the EP 1 141 447 B1 , and contain up to 50 wt. % magnesium. Where there is direct contact between aluminium and magnesium components, coatings of this kind serve to protect the aluminium from attack by the alkaline corrosion products of the magnesium. However, improved high-temperature stability compared to that of a “conventional”, zinc-based anticorrosion coating is not described in the literature. These coatings are technically difficult to apply and are only suitable for individual parts. In consequence, they are not used on a wide industrial scale. According to the WO 2005/035835 A1, moreover, the coating bonds poorly to the substrate. A coating of this kind can therefore not be used for forming processes, such as cold forming or the hot forming of sheet metal.

Generally speaking, the preparation of a magnesium-containing coating that is resistant to environmental influences is only possible anyway if a sizeable proportion of additional alloying constituents (e.g. aluminium with up to 50% magnesium) is included, since a coating of pure magnesium itself shows a strong tendency to corrode, even to the extent of pitting, and in a neutral salt spray test, for example, is severely corroded after just one day.

The object of the invention is thus to provide an economical process for cathodic corrosion protection of metal for a broad range of applications.

This object is established according to the invention by a method for producing deformable corrosion protection layers on a metallic surface, consisting of the following steps:

a) Mixing 5 to 95 wt. % metallic magnesium, zinc, aluminium or titanium particles, or mixtures or alloys containing at least one of these metals, in the form of pigments, powders, pastes (flakes) or pellets with 5 to 95 wt. % of at least one metal compound, wherein a reaction between the metal particles and metal compound(s) results in surface-modified metal particles;

b) Applying the resulting surface-modified metal particles to the metallic surface;

c) Hardening the layer produced from the surface-modified metal particles at temperatures between room temperature and 500° C.

It was found within the context of the invention that, unlike conventional zinc flake coatings, the coatings according to the invention can be (de)formed. It was also found that the metal substrate coated according to the method of the invention can be deformed, overpainted, welded, coated and coloured, and reflects heat. Surprisingly, it was found in addition that also a coating with titanium dioxide on zinc/aluminium provides a composite of steel and aluminium with cathodic corrosion protection.

A distinct advantage of magnesium pigments over zinc pigments is their substantially higher melting and boiling points. For pure magnesium, these are 650 and 1,107° C. respectively. These parameters on their own allow the use of magnesium at much higher temperatures than are possible with zinc (MP=415° C., BP=907 ° C.). Having a standard potential of −2.36V for the redox pair Mg/Mg²⁺, magnesium is very much a base, i.e. non-precious, element, and is therefore used, for example, as the sacrificial anode in corrosion protection systems for steel. Where magnesium or magnesium/aluminium is used as metal pigment, the coating produced according to the invention is suitable for permanent applications at temperatures from −50 to 650° C., preferably between room temperature and 600° C., more preferably between room temperature and 500° C. Brief exposure to temperatures up to 1200° C., (for example for the hot-forming of solid steel components), preferably up to 1,000° C. (for example for the hot-forming, heat-treatment and hardening of sheet steel or the semicold forming of solid steel components) is also possible. The term “brief” as used here means a period of less than 20 minutes, preferably less than 10 minutes and best of all less than 7 minutes.

Surprisingly, it was found that the corrosion tendency of magnesium particles or zinc particles in the magnesium-containing or zinc-containing layers can be effectively prevented by coating the surface of each individual particle with a thin layer containing electrically conducting or semiconducting constituents, without preventing the active corrosion-protection effect of the magnesium or zinc, in themselves very base metals. The metal particles are passivated “in situ” by the metal compound, preventing the formation of white rust typical of conventional zinc coatings hardenable at room temperature.

Where magnesium is used as pigment, the layers according to the invention still provide active cathodic corrosion protection even after continuous use at temperatures up to 600° C. This was demonstrated, for example, by the fact that layers according to the invention that had been subjected to several days' heat treatment and then damaged (scratched) right down to the substrate metal (mild steel) still prevented the formation of red rust at the damaged site or on the surface during a subsequent corrosion test lasting 200 hours (neutral salt spray test according to ISO 9227 (DIN 50021)). Even after brief heating to temperatures up to 1,000° C. for 10 minutes, the active corrosion protection provided by the coating of the invention is still so good that no red rust appears after more than 100 h salt spray test. Brief, high-temperature loading of this kind may occur, for example, during the forming, hardening, forging and heat-treatment of steel.

It is within the scope of the invention that the coating agent is applied in layer thicknesses of 2 to 25 μm, preferably in layer thicknesses of 2 to 15 μm and more preferably in layer thicknesses of 2 to 10 μm.

It transpired within the scope of the invention that distinctly thinner layers than in the prior art suffice to produce very good corrosion protection.

The invention provides for the use of 10 to 80 wt. %, more preferably 25 to 75 wt. % and most preferably 40 to 60 wt. % metallic magnesium, zinc, aluminium or titanium particles in the form of pigments, powders, pastes (flakes) or pellets.

It is within the scope of the invention to use 20 to 90 wt. %, more preferably 25 to 75 wt. % and most preferably 40 to 60 wt. % metal compound.

It is preferable for the particles, pigments, powders, pastes (flakes) or pellets to have an individual grain size of 100 nm to 100 μm, more preferably of 1 μm to 30 μm.

A preferred embodiment of the invention consists in that the metal compound is a metal alkoxide, a metal salt or a mixture of metal alkoxides and/or metal salts.

In this connection, it is preferable for the metal alkoxide to be selected from the group consisting of titanium alkoxide, especially titanium butylate, titanium propylate or titanium isopropylate, zirconium alkoxide, aluminium alkoxide and tin alkoxide.

According to the invention, the metal salt is selected from the group consisting of carbonates, nitrates, nitrites, sulphates, sulphites, phosphites, phosphates, phosphonates, hydroxides, oxides, borates, chlorides, chlorates, acetates, formiates, citrates, oxalates, succinates, lactates, oleates and stearates of iron, manganese, magnesium, silicon, cobalt, copper, nickel, chromium, zinc, tin, aluminium, zirconium, titanium, vanadium, molybdenum, tungsten, silver or mixtures thereof.

An embodiment of the invention consists in that the metal compound is dissolved in a solvent, the solvent preferably containing or being water, alcohol, protic or aprotic solvents, the solvent more preferably being or containing toluene, butyl glycol, xylene or isopropanol.

It is within the scope of the invention that, in step a), 0-20 wt. % lubricants, in particular boron nitride (BN), molybdenum disulphide (MoS₂), tungsten disulphide (WS₂), polytetrafluoroethylene particles (PTFE) or silicones, waxes, oils or soaps, hydrophobizing or oleophobizing additives or hydrophilizing additives, graphite, organophosphoric compounds, soot, antisettling agents such as aerosils, colorants, in particular inorganic pigments such as iron oxide (FeOx), are added.

The invention furthermore provides for the addition in step a) of 0-30 wt. % other metal particles of iron, copper, tin, chromium, nickel, stainless steel or mixtures thereof.

It is within the scope of the invention that, in step a), 0-30 wt. %, preferably 2 to 20 wt. %, more preferably 5 to 10 wt. % aminosilanes, blocked phosphates, Lewis acids, Lewis bases, acids or bases are added as crosslinking catalysts.

It is within the scope of the invention that, in step b), application of the resulting surface-modified metal particles onto the metallic surface is by way of a wet-chemical process, in particular by spray painting, dip coating, flooding, roller application, roll-coating, brush coating, printing, spinning, by knife application, in an emulsion in water, by vacuum evaporation, currentless application, electroplating or in powder form.

It is to advantage that the metallic surface is a metal, metal alloy, coil or coated metal, in particular of steel, aluminium, magnesium, magnesium-aluminium, zinc, iron, stainless steel, copper, tin, lead, brass, bronze, nickel, chromium, titanium, vanadium, manganese or combinations thereof, in the form of an individual component or of a combination of the same or different metals.

It is within the scope of the invention that, in step c), hardening is carried out at temperatures ranging from room temperature to 500° C., preferably between room temperature and 350° C., more preferably between 250 and 350° C., for a period of between 30 s and 1 day, preferably for a period of between 30 s and 1 h, more preferably for a period of between 30 s and 5 minutes.

A refinement of the invention consists in that hardening is followed by a tempering step performed at temperatures ranging from 250° C. to approx. 700° C. and lasting for a few seconds to some hours.

Last but not least, the scope of the invention also includes use of the method of the invention for producing deformable corrosion protection layers on components for buildings, road, air, water, underwater, farm, construction, space and rail vehicles, in particular motor vehicles and motor vehicle attachments, motors/engines and motor/engine attachments, farm machinery, construction machinery, bridges, cranes, shafts, cable cars, industrial plant, technical equipment, power plants, lamps, masts, housings, covers or protective devices, or on fasteners, in particular screws and bolts.

The scope of the invention furthermore includes use of the method of the invention to produce an active welding primer for steel or galvanized steel, which is also weldable.

The invention is described below in detail by reference to embodiments:

### Example 1:

100 g butyl glycol are poured over a mixture of 100 g fine, flaky zinc powder and 15 g of likewise flaky aluminium pigment paste. The mixture is left to stand in a closed vessel for 24 h and then homogenised for 2 h with a slow stirrer.

50 g tetra-n-butyl-orthozirconate are stirred into the reaction mixture under an atmosphere of dried nitrogen, the mixture homogenised for 1 h with a slow stirrer and then refluxed for 12 h (boiling point of tetra-n-butyl-orthozirconate=117° C.). The zinc and aluminium particles are surface-modified with the organometal component during this process. After the reaction mixture has cooled down to room temperature again, a further 100 g tetra-n-butyl-orthozirconate are stirred in under the dried-nitrogen atmosphere, and stirring continued for another 5 h.

During application, the liquid coating material is stirred continuously to prevent solid components from settling.

The coating material is applied by roll applicator to both sides of degreased and cleaned steel sheets in a wet film thickness of 40-50 μm, and stoved for 5 minutes at 250° C.

The coated steel sheets are tempered in a suitable electric furnace for 30 minutes at 300° C. This makes the coating bond so strongly to the steel surface that the sheet, with its coating, can be formed into a component without the coating chipping off.

### Example 2:

100 g of a fine magnesium powder with a particle size smaller than 20 μm (from Ecka), are dispersed in 100 g butyldiglycol acetate. A solution of 20 g chromium(III) nitrate nonahydrate in 100 g butyl glycol is added slowly, with constant stirring, to the dispersion. The reaction mixture warms up during the addition. The speed of addition is selected such that the temperature of the reaction mixture does not rise higher than 50° C.

The butyl glycol is distilled off under vacuum with a rotary evaporator, at a bath temperature of 50° C.

After the reaction mixture has cooled down to room temperature again, 120 g tetra-isopropylorthotitanate are added and stirred with the modified magnesium powder until a homogeneous, paint-like dispersion is obtained. The mixture is refluxed for 12 h under a dried-nitrogen atmosphere (boiling point of tetra-isopropylorthotitanate=232° C., boiling range of butyldiglycol acetate=238-248° C.).

After the reaction mixture has cooled down to room temperature, 50 g of a blocked phosphate catalyst are added, obtainable, for example, from King Industries under the name Nacure, and stirred in homogeneously for 30 minutes.

The viscosity is adjusted to 20 s (flow time from a 4 mm DIN flow cup) by adding butyl glycol.

The coating material is introduced into a constantly stirred dip-coating bath.

A component assembled, for example, by welding, or steel/aluminium sheet where the two metals make direct contact with each other, is dipped into the bath in such a manner that also the weld is wetted completely by the coating material and the latter is able to penetrate to a depth of a few millimetres into the space between the metal sheets at the welded joint. After removal of the coated component, this is transferred to a hot-air furnace where the coating is stoved for 30 minutes at 250° C.

Thanks to the coating, sheet metal or components are obtained that are entirely actively (cathodically) protected against corrosion, i.e. the baser aluminium, too, is protected at the point of contact against corrosion.

### Example 3:

100 g butyl glycol are poured over a mixture of 100 g fine, flaky zinc powder and 15 g of likewise flaky aluminium pigment paste. The reaction mixture is left to stand in a closed vessel for 24 h and then homogenised for 2 h with a slow stirrer.

50 g tetra-n-butyl-orthotitanate are stirred into the reaction mixture under an atmosphere of dried nitrogen, the mixture homogenized for 1 h with a slow stirrer and then refluxed for 12 h. The zinc and aluminium particles are surface-modified with the organometal component during this process. After the reaction mixture has cooled down to room temperature again, a further 100 g tetra-n-butyl-orthotitanate are stirred in under the dried-nitrogen atmosphere, and stirring continued for another 5 h.

During application, the liquid coating material is stirred continuously to prevent solid components from settling.

The coating material is applied by roll applicator to both sides of degreased and cleaned steel sheets in a wet film thickness of 40-50 μm, and stoved for 5 minutes at 250° C.

The coated steel sheets are tempered in a suitable electric furnace for 30 minutes at 300° C. This makes the coating bond so strongly to the steel surface that the sheet, with its coating, can be formed into a component without the coating chipping off.

1. Method for producing deformable corrosion protection layers on a metallic surface, consisting of the following steps:
a) Mixing 5 to 95 wt. % metallic magnesium, zinc, aluminum or titanium particles, or mixtures or alloys containing at least one of these metals, in the form of pigments, powders, pastes (flakes) or pellets with 5 to 95 wt. % of at least one metal compound, wherein a reaction between the metal particles and metal compound(s) results in surface-modified metal particles;
b) Applying the resulting surface-modified metal particles to the metallic surface;
c) Hardening the layer produced from the surface-modified metal particles at temperatures between room temperature and 350° C.

2. Method according to claim 1, wherein the coating agent is applied in layer thicknesses of 2 to 25 μm, preferably in layer thicknesses of 2 to 15 μm and more preferably in layer thicknesses of 2 to 10 μm.

3. Method according to claim 1, wherein 10 to 80 wt. %, more preferably 25 to 75 wt. % and most preferably 40 to 60 wt. % metallic magnesium, zinc, aluminum or titanium particles in the form of pigments, powders, pastes (flakes) or pellets are used.

4. Method according to claim 1, wherein 20 to 90 wt. %, more preferably 25 to 75 wt. % and most preferably 40 to 60 wt. % metal compound are used.

5. Method according to claim 1, wherein the particles, pigments, powders, pastes (flakes) or pellets have an individual grain size of 100 nm to 100 μm, more preferably of 1 μm to 30 μm.

6. Method according to claim 1, wherein the metal compound is a metal alkoxide, a metal salt or a mixture of metal alkoxides and/or metal salts.

7. Method according to claim 6, wherein the metal alkoxide is selected from the group consisting of titanium alkoxide, especially titanium butylate, titanium propylate or titanium isopropylate, zirconium alkoxide, aluminum alkoxide and tin alkoxide.

8. Method according to claim 6, wherein the metal salt is selected from the group consisting of carbonates, nitrates, nitrites, sulphates, sulphites, phosphites, phosphates, phosphonates, hydroxides, oxides, borates, chlorides, chlorates, acetates, formiates, citrates, oxalates, succinates, lactates, oleates and stearates of iron, manganese, magnesium, silicon, cobalt, copper, nickel, chromium, zinc, tin, aluminum, zirconium, titanium, vanadium, molybdenum, tungsten, silver or mixtures thereof.

9. Method according to claim 1, wherein the metal compound is dissolved in a solvent, the solvent preferably containing or being water, alcohol, protic or aprotic solvents, the solvent more preferably being or containing toluene, butyl glycol, xylene or isopropanol.

10. Method according to claim 1, wherein, in step a), 0-20 wt. % lubricants, in particular boron nitride (BN), molybdenum disulphide (MoS₂), tungsten disulphide (WS₂), polytetrafluoroethylene particles (PTFE) or silicones, waxes, oils or soaps, hydrophobizing or oleophobizing additives or hydrophilizing additives, graphite, organophosphoric compounds, soot, antisettling agents such as aerosils, colorants, in particular inorganic pigments such as iron oxide (FeOx), are added.

11. Method according to claim 1, wherein, in step a), 0-30 wt. % other metal particles of iron, copper, chromium, nickel, stainless steel or mixtures thereof is added.

12. Method according to claim 1, wherein, in step a), 0 to 30 wt. %, preferably 2 to 20 wt. %, more preferably 5 to 10 wt. % aminosilanes, blocked phosphates, Lewis acids, Lewis bases, acids or bases are added as crosslinking catalysts.

13. Method according to claim 1, wherein, in step b), application of the resulting surface-modified metal particles onto the metallic surface is by way of a wet-chemical process, in particular by spray painting, dip coating, flooding, roller application, roll-coating, brush coating, printing, spinning, by knife application, in an emulsion in water, by vacuum evaporation, currentless application, electroplating or in powder form.

14. Method according to claim 1, wherein the metallic surface is a metal, metal alloy, coil or coated metal, in particular of steel, aluminum, magnesium, magnesium-aluminum, zinc, iron, stainless steel, copper, lead, brass, bronze, nickel, chromium, titanium, vanadium, manganese or combinations thereof, in the form of an individual component or of a combination of the same or different metals.

15. Method according to claim 1, wherein, in step c), hardening is carried out for a period of between 30 s and 1 h, more preferably for a period of between 30 s and 5 min.

16. Method according to claim 1, wherein hardening is followed by a tempering step performed at temperatures ranging from 250° C. to approx. 700° C. and lasting for a few seconds to some hours.

17. Use of the method according to claim 1 for producing deformable corrosion protection layers on components for buildings, road, air, water, underwater, farm, construction, space and rail vehicles, in particular motor vehicles and motor vehicle attachments, motors/engines and motor/engine attachments, farm machinery, construction machinery, bridges, cranes, shafts, cable cars, industrial plant, technical equipment, power plants, lamps, masts, housings, covers or protective devices, or on fasteners, in particular screws and bolts.
